(19) United States
(12) Patent Application Publication
(10) Pub. No.: US 2006/0017090 A1
(43) Pub. Date: Jan. 26, 2006

(54) Semiconductor device and method of manufacturing the same

(75) Inventors: Naomi Fukumaki, Kawasaki (JP); Yoshitake Kato, Kawasaki (JP); Ken Inoue, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/180,675

(22) Filed: Jul. 14, 2005

(30) Foreign Application Priority Data
Jul. 23, 2004 (JP) 2004-216515

(51) Int. Cl. H01L 29/94

(52) U.S. Cl. 257/309

(57) ABSTRACT

A semiconductor device includes a cylinder-shaped capacitor. The capacitor includes a second insulating layer formed with a recessed portion formed on a semiconductor substrate, a cylinder shaped lower electrode formed in the recessed portion, a capacitance layer formed on the lower electrode, and an upper electrode formed on the capacitance layer. The upper electrode includes a first metal layer formed by PVD and a second metal layer formed thereafter by CVD, and the cylinder sidewall of the first metal layer has a thickness of 2 nm or less.

This application is based on Japanese patent application No. 2004-216515, the content of which is incorporated hereinto by reference.

### BACKGROUND OF THE INVENTION

1. Field of the Invention

The present invention relates to a semiconductor device including a cylinder-shaped MIM (Metal-Insulator-Metal) capacitor, and to a method of manufacturing the same.

2. Description of the Related Art

Along with the ongoing micronization in dimensions and progress in integration level of DRAMs, how to secure a sufficient capacitance value of a cell has come up as an important issue to be addressed. Techniques of securing a sufficient cell capacitance include increasing the surface area of the capacitor, and increasing the specific dielectric constant of the capacitor dielectric.

For increasing the surface area of the capacitor, a cylindrical shape is adopted for the capacitor. Also, for increasing the specific dielectric constant of the capacitor dielectric, a high dielectric constant film (hereinafter, simply referred to as a “high-k film) such as a Ta₂O₅ film is employed.

JP-A No. H11-354738 proposes a DRAM cell constituted as above. However, employing a high-k film such as a Ta₂O₅ film as a capacitance layer leads to such a drawback that, since the Ta₂O₅ film is a multi-element oxide film which is structurally unstable, the Ta₂O₅ film is prone to react against a lower electrode or an upper electrode, to thereby incur degradation in characteristics such as an increase in leakage current. Besides, when the high-k film reacts against the upper electrode or the lower electrode, the high-k film loses a part of its physical thickness, thus resulting in reduction of the capacitance value.

JP-A No. 2004-64091 discloses a technique of forming a first upper electrode by a PVD process, and then a second upper electrode by a CVD process, when forming an upper electrode for a capacitor. This technique allows quickly forming the upper electrode having a greater thickness, which does not incur degradation in electrical characteristics.

Through the studies made by the present inventors, it has now been discovered that, when employing a high-k film such as a Ta₂O₅ film as a capacitance layer, forming first a PVD layer which efficiently crystallizes on a capacitance layer, and second a CVD layer which provides an extensive coverage on the PVD layer is effective in reducing the leakage current and preventing the degradation in capacitance characteristics.

It has also been proven that forming the PVD layer in an excessive thickness weakens the initial leakage current of the capacitor.

### SUMMARY OF THE INVENTION

According to the present invention, there is provided a semiconductor device including a cylinder-shaped capacitor, comprising a semiconductor substrate; an insulating layer formed on the semiconductor substrate and formed with a recessed portion; a cylinder-shaped lower electrode constituted of a metal material formed in the recessed portion; a capacitance layer formed on the lower electrode; and an upper electrode formed on the capacitance layer; wherein the upper electrode includes a first metal layer formed by a PVD process and a second metal layer formed by a CVD process and the first metal layer is formed to have a thickness of 2 nm or less at the cylinder sidewall.

The semiconductor device thus constructed, including the first metal layer formed by a PVD process on the capacitance layer, can suppress an increase in leakage current and degradation in capacitance characteristics. Also, forming the first metal layer such that the thickness of the cylinder sidewall becomes 2 nm (20 angstrom) or less allows maintaining an expected initial leakage current, as well as the capacitance characteristics of the capacitor. A lower limit of the cylinder sidewall thickness of the first metal layer is not specifically determined, but may be set at 0.1 nm, for example. Such configuration allows maintaining the expected effect of suppressing an increase in leakage current and degradation in capacitance characteristics.

JP-A No. 2004-64091 refers to forming a PVD-TiN layer having a thickness of approx. 70 angstrom (7 nm) on a sidewall of a concave hole, without applying a bias charge to the substrate. This is supported by the description that vapor-depositing the PVD-TiN all over the concave hole improves the leakage current characteristic.

However, through the studies made by the present inventors, it has been discovered that the first metal layer formed by PVD should not be thicker than a certain limit, otherwise the initial leakage current of the capacitor is weakened. This finding will be described in details with respect to examples. The present inventors have discovered that forming the cylinder sidewall of the first metal layer in a thickness not exceeding 2 nm is effective in preventing the degradation in initial leakage current of the capacitor. In order to form the cylinder sidewall of the first metal layer in a thickness not exceeding 2 nm, the optimal depositing condition of the first metal layer should be established. The present inventors have examined various combinations of (i) T/S distance (distance between a target and the substrate), (ii) power, (iii) temperature of the substrate, and (iv) pressure in the sputtering chamber, to thereby establish a depositing condition of the first metal layer that makes the thickness of the cylinder sidewall 2 nm or less. Forming the first metal layer under such condition assures that the initial leakage current as well as the capacitance characteristics of the capacitor can be maintained at an expected level.

In the semiconductor device according to the present invention, the capacitance layer may be constituted of a high-k film.

A typical example of the high-k film is a Ta₂O₅ film. When employing such a film, forming the amorphous second metal layer by CVD right upon the high-k film may incur degradation in capacitance characteristic, because the nature of the second metal layer at an interface with the high-k film has not been modified, and hence a low dielectric constant layer is prone to be formed in a region close to the interface. According to the present invention, however, since the first metal layer which efficiently crystallizes is provided between the high-k film and the second metal layer, such degradation in capacitance characteristics can be prevented.

In the semiconductor device according to the present invention, the first metal layer and the second metal layer of the upper electrode may be constituted of a titanium nitride (TiN).

In the semiconductor device according to the present invention, the lower electrode may be constituted of a TiN.

In the semiconductor device according to the present invention, the cylinder sidewall of the second metal layer may be formed in a thickness of 20 nm or more.

The total thickness of the first metal layer and the second metal layer have to reach a certain level, otherwise the capacitance layer is prone to be damaged during a process after the deposition of the second metal layer. On the other hand, if the first metal layer is formed to be excessively thick, the capacitance layer is damaged during the deposition of the first metal layer, and the initial leakage current of the capacitor is thereby lowered, as already stated. Accordingly, the present invention has established the above thickness, to be given to the second metal layer. Such configuration prevents the capacitance layer from being damaged in a subsequent process, and suppresses an increase in leakage current.

In the semiconductor device according to the present invention, the second metal layer of the upper electrode may be formed under a temperature not exceeding 440 degree centigrade.

Depositing the second metal layer under such a temperature condition can assure satisfactory coverage performance of the second metal layer. Also, the capacitance layer can be prevented from being damaged by a chemical gas such as hydrogen, during the deposition of the second metal layer.

In the semiconductor device according to the present invention, the upper electrode may be formed on the second metal layer, and may further include a buried metal layer that fills the recessed portion.

The buried metal layer may be constituted of tungsten (W), and formed by a CVD process. According to the present invention, since the first metal layer which efficiently crystallizes is provided right upon the capacitance layer, the capacitance layer can be prevented from being damaged during the deposition of the buried metal layer. Also, forming the second metal layer in a greater thickness allows further reducing the damage of the capacitance layer during the deposition of the buried metal layer. The buried metal layer also serves to reduce the resistance of the upper electrode.

According to the present invention, there is provided a method of manufacturing a semiconductor device, comprising forming an insulating layer on a semiconductor substrate; forming a recessed portion in the insulating layer; forming in the recessed portion a cylinder-shaped capacitor, including a lower electrode constituted of a metal material, a capacitance layer formed on the lower electrode and an upper electrode formed on the capacitance layer; wherein the step of forming the capacitor includes forming the upper electrode by forming a first metal layer by a PVD process such that a thickness of a sidewall of the cylinder becomes 2 nm or less, and forming a second metal layer on the first metal layer by a CVD process.

In the method of manufacturing thus arranged, the step of forming the first metal layer may include performing a long-throw sputtering process, with a spacing of 150 mm or more between a target and the substrate.

Such method allows forming the first metal layer in an appropriate thickness, such that the thickness of the cylinder sidewall becomes 2 nm or less.

In the method of manufacturing arranged as above, the step of forming the second metal layer may be performed under a temperature not exceeding 440 degree centigrade.

Accordingly, the present invention effectively reduces a leakage current and prevents degradation in capacitance characteristics and initial leakage current, in a semiconductor device including a MIM capacitor.

### BRIEF DESCRIPTION OF THE DRAWINGS

The above and other objects, advantages and features of the present invention will be more apparent from the following description taken in conjunction with the accompanying drawings, in which:

FIGS. 1A and 1B are schematic cross-sectional views showing a semiconductor device according to an embodiment of the present invention;

FIGS. 2A to 2E are schematic cross-sectional views sequentially showing a manufacturing process of the semiconductor device according to the embodiment;

FIGS. 3F to 3H are schematic cross-sectional views sequentially showing a manufacturing process of the semiconductor device according to the embodiment;

FIG. 4 is a graph showing a relation between a thickness of the cylinder sidewall of the PVD layer and a rate of the pass chips of a leakage current test;

FIG. 5 is a graph showing a relation between a thickness of the cylinder sidewall of the CVD layer and a rate of the pass chips of a leakage current test; and

FIG. 6 is a graph showing a relation between a temperature for depositing the CVD layer and a rate of the pass chips of a leakage current test.

### DETAILED DESCRIPTION OF THE INVENTION

The present invention will be now described herein with reference to illustrative embodiments. Those skilled in the art will recognize that many alternative embodiments can be accomplished using the teachings of the present invention and that the invention is not limited to the embodiments illustrated for explanatory purposed.

Referring to the accompanying drawings, an embodiment of the present invention will be described hereunder. In all the drawings, similar constituents are given the same numeral, and description thereof will be appropriately omitted.

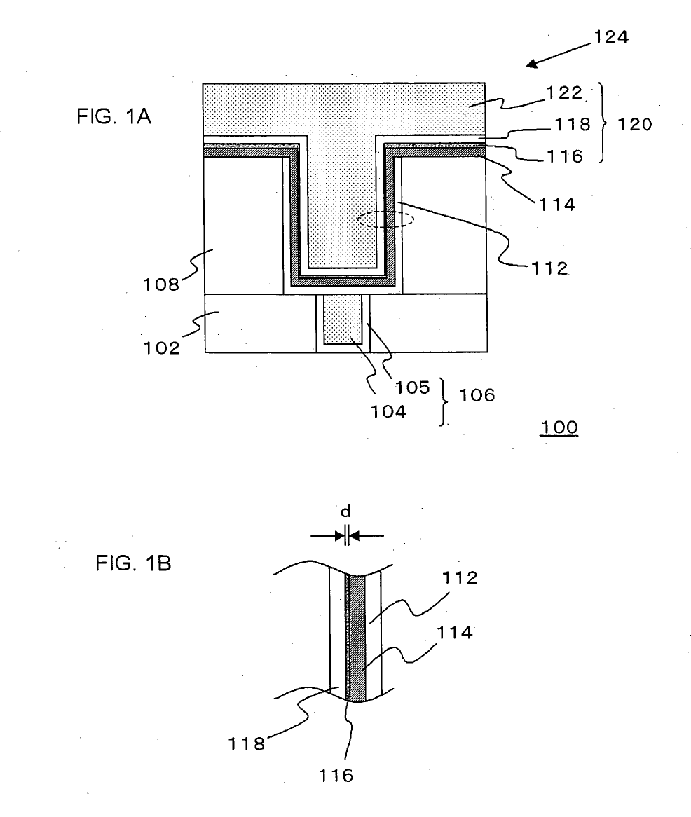

FIGS. 1A and 1B are schematic cross-sectional views showing a semiconductor device 100 according to the embodiment. The semiconductor device 100 includes a cylinder-shaped MIM capacitor 124.

Referring to FIG. 1A, the capacitor 124 includes a lower electrode 112, a capacitance layer 114 and an upper electrode 120. In this embodiment, the lower electrode 112 is constituted of a metal material such as TiN, and may be formed by a CVD process. The capacitance layer 114 may be constituted of a high-k film such as a Ta₂O₅ film.

The upper electrode 120 includes a PVD layer 116, a CVD layer 118 and a buried metal layer 122. The PVD layer 116 may be constituted of TiN deposited by a PVD process. The CVD layer 118 may be constituted of TiN deposited by a CVD process. The buried metal layer 122 may be constituted of W, deposited by for example a CVD process.

Performing the CVD process to form the lower electrode 112 and the CVD layer 118 results in formation of an amorphous TiN layer that offers excellent coverage performance. However, if the CVD layer 118 is formed directly on the capacitance layer 114, a low dielectric constant layer may be formed in a region close to an interface between the CVD layer 118 and the capacitance layer 114 and the capacitance characteristics may be thereby degraded, since the film nature of the CVD layer 118 at such interface has not been modified.

Accordingly, in this embodiment, the PVD layer 116 which efficiently crystallizes is interposed between the capacitance layer 114 and the CVD layer 118. Such configuration inhibits the formation of the low dielectric constant layer between the upper electrode 120 and the capacitance layer 114, thus maintaining satisfactory capacitance characteristics of the capacitor 124.

FIG. 1B is an enlarged cross-sectional view showing the portion of the capacitor 124 enclosed by a broken line in FIG. 1A.

As stated above, providing the PVD layer 116 between the CVD layer 118 and the capacitance layer 114 of the upper electrode 120 allows maintaining satisfactory capacitance characteristics of the capacitor 124. However, when the thickness “d” of the PVD layer 116 is thicker than a certain value, the capacitance layer 114 formed under the PVD layer 116 is damaged when depositing the PVD layer 116, which results in degradation in initial leakage current of the capacitor 124. Besides, the fluctuation of the in-plane characteristic of the capacitor 124 becomes larger.

In this embodiment, the PVD layer 116 is formed such that the thickness “d” of the cylinder sidewall becomes 2 nm or less. Setting thus the upper limit of the thickness “d” of the PVD layer 116 allows preventing the capacitance layer 114 formed thereunder from being damaged during the deposition of the PVD layer 116, and hence the initial leakage current of the capacitor 124 from being lowered. A lower limit of the thickness d of the PVD layer 116 is not specifically determined, but may be set at 0.1 nm for example. Such a thickness range allows maintaining the satisfactory capacitance characteristics of the capacitor 124 as expected.

On the other hand, it is desirable to form the CVD layer 118 of the upper electrode 120 in a certain level of thickness, in order to prevent the capacitance layer 114 from being damaged by hydrogen or plasma in the deposition process of the buried metal layer 122 or thereafter. Accordingly, it is preferable to form the CVD layer 118 such that the thickness of the cylinder sidewall becomes 20 nm or more.

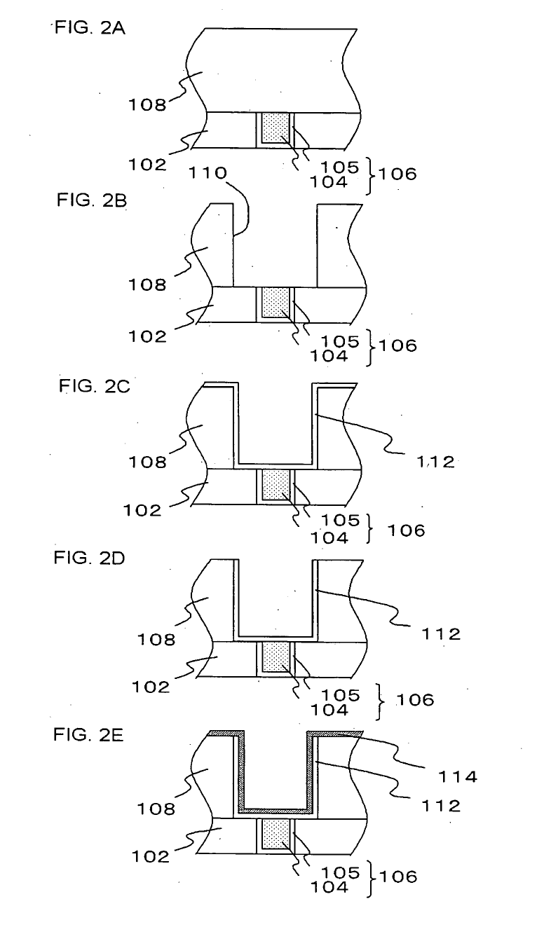

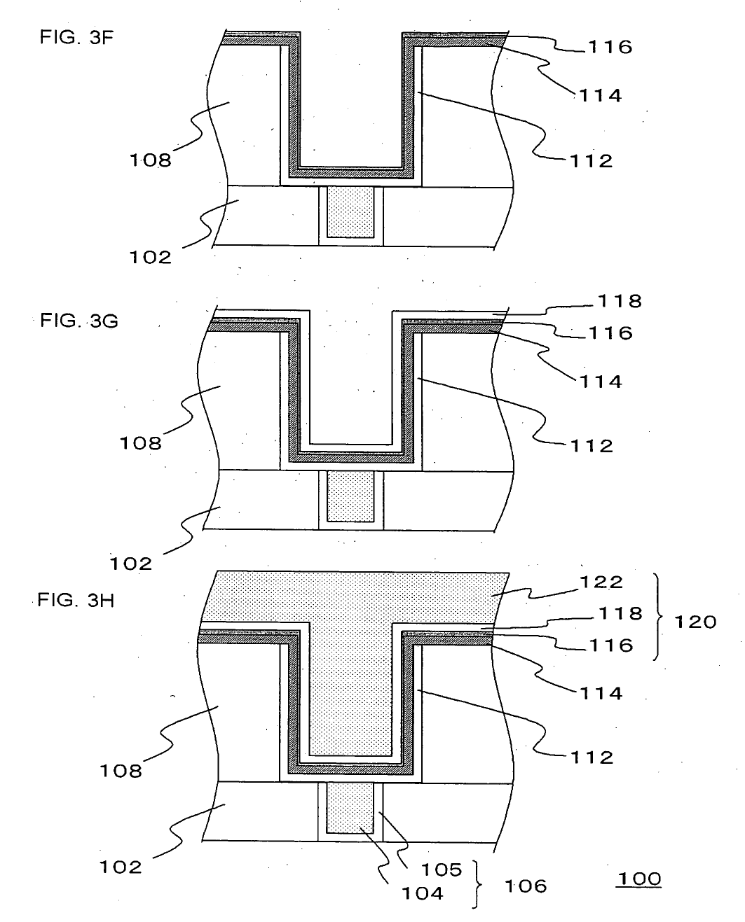

FIGS. 2A through 3H are cross-sectional views sequentially showing the manufacturing process of the semiconductor device 100 shown in FIG. 1.

On a first insulating layer 102 formed on a semiconductor substrate (not shown), a plug 106 including a metal layer 104 and a barrier metal layer 105 is provided. The first insulating layer 102 is constituted of for example SiO₂ or SiOC. The metal layer 104 may be constituted of W, for example. The barrier metal layer 105 may be constituted of Ti, TiN, Ta, or TaN, for example. On the first insulating layer 102 thus constituted, a SiON layer (not shown) is formed so as to serve as an etching stopper, and a second insulating layer 108 is formed on the SiON layer (FIG. 2A). The second insulating layer 108 is constituted of SiO₂, for example.

Then a recessed portion 110 is formed on the second insulating layer 108 by a known lithography process, thus to expose an upper face of the plug 106 (FIG. 2B). Thereafter, the lower electrode 112 is formed all over the second insulating layer 108 (FIG. 2C). The lower electrode 112 may be constituted of for example TiN, TaN, or WN. Among these TiN is preferably used. Such structure enhances the adhesion to the adjacent layers. The thickness of the lower electrode 112 in the stacking direction may be determined in a range of 1 nm to 40 nm, for example. Also, the cylinder sidewall of the lower electrode 112 may be formed in a thickness of 2 nm to 80 nm.

On the lower electrode 112, a sacrifice layer (not shown) is formed so as to fill the recessed portion 110. Then etching is performed on the sacrifice layer and the lower electrode 112 so as to remove a portion of the lower electrode 112 present outside the recessed portion 110. The sacrifice layer remaining in the recessed portion 110 is then removed by etching (FIG. 2D).

Then the capacitance layer 114 is formed on the second insulating layer 108 and the lower electrode 112 (FIG. 2E). The capacitance layer 114 is constituted of a high-k film such as a Ta₂O₅ film. The thickness of the capacitance layer 114 in the stacking direction may be determined in a range of 1 nm to 50 nm, for example. Also, the cylinder sidewall of the capacitance layer 114 may be formed in a thickness of 1 nm to 50 nm.

Now the upper electrode 120 is formed on the capacitance layer 114. The upper electrode 120 is constituted of for example TiN. To be more detailed, the PVD layer 116 is first formed on the capacitance layer 114 (FIG. 3F). The thickness of the PVD layer 116 in the stacking direction may be determined in a range of 5 nm to 50 nm, for example. Also, the cylinder sidewall of the PVD layer 116 may be formed in a thickness of 2 nm or less.

In this embodiment, the desired thickness of the cylinder sidewall of the PVD layer 116 can be attained by appropriately controlling the following conditions, when depositing the PVD layer 116.

(i) T/S distance (distance between a target and the substrate);

(ii) Power;

(iii) substrate temperature; and

(iv) pressure in the sputtering chamber.

A specific example is shown below.

T/S distance: 150 to 350 mm, LTS-TiN (long-throw sputtering)

Power: 5 kw to 20 kw

Wafer temperature: 280 to 380 degree centigrade

Pressure: 0.5 mTorr to 2.5 mTorr

Performing a sputtering process under such conditions enables forming the PVD layer 116 having the cylinder sidewall of 2 nm or less in thickness. Further, with respect to the conditions (i) to (iv), appropriately adjusting the T/S distance to a longer side, the power and the pressure to a higher side allows forming the PVD layer 116 having a still thinner cylinder sidewall. Here, a bias voltage is not applied in any of the cases.

Then the CVD layer 118 is formed on the PVD layer 116 (FIG. 3G). The CVD layer 118 may be formed by a MO-CVD (Metal Organic Chemical Vapor Deposition) process, or an ALD (Atomic Layer Deposition) process. The thickness of the CVD layer 118 in the stacking direction may be determined in a range of 10 nm to 80 nm, for example. Also, the cylinder sidewall of the CVD layer 118 may be formed in a thickness of 20 nm or more.

The CVD layer 118 is preferably formed under a temperature not exceeding 440 degree centigrade. Such a temperature condition assures the excellent coverage performance of the CVD layer 118. Such a condition also serves to prevent the capacitance layer 114 from being damaged by a chemical gas such as hydrogen, during the deposition of the CVD layer 118. A lower limit of the temperature for depositing the CVD layer 118 is not specifically determined, but may be set at 350 degree centigrade, for example. Such a temperature range allows achieving a high throughput, as well as maintaining satisfactory in-plane uniformity.

Finally the buried metal layer 122 is formed on the CVD layer 118 (FIG. 3H). The buried metal layer 122 is constituted of W, for example. Providing the buried metal layer 122 allows maintaining the resistance of the upper electrode 120 at a low level.

Examples will be described here below.

### FIRST EXAMPLE

Similar steps to those described referring to FIGS. 2A through 3H have been taken so as to form the capacitor 124. In this example, different conditions have been applied to the deposition of the PVD layer 116 (TiN), such that the thickness of the cylinder sidewall of the PVD layer 116 becomes 1.0 to 3.0 nm. In this example, the capacitance layer 114 was constituted of a Ta₂O₅ film; the CVD layer 118 was constituted of TiN; and the buried metal layer 122 was constituted of W. The cylinder sidewall of the CVD layer 118 has been formed a thickness of 30 nm, and the CVD layer 118 has been deposited under a temperature of 435 degree centigrade.

The PVD layer 116 has been deposited under the following conditions:

(a) T/S distance 300 mm, power 15 kw, wafer temperature 350 degree centigrade, pressure 2 mTorr, LTS-TiN (long-throw sputtering);

(b) T/S distance 50 mm, power 3 kw, wafer temperature 300 degree centigrade, pressure 0.3 mTorr, LTS-TiN (long-throw sputtering);

Under the condition of (a), the PVD layer 116 has been formed with the cylinder sidewall of 2 nm or less in thickness. Under the condition of (b), the PVD layer 116 has been formed with the cylinder sidewall thicker than 2 nm.

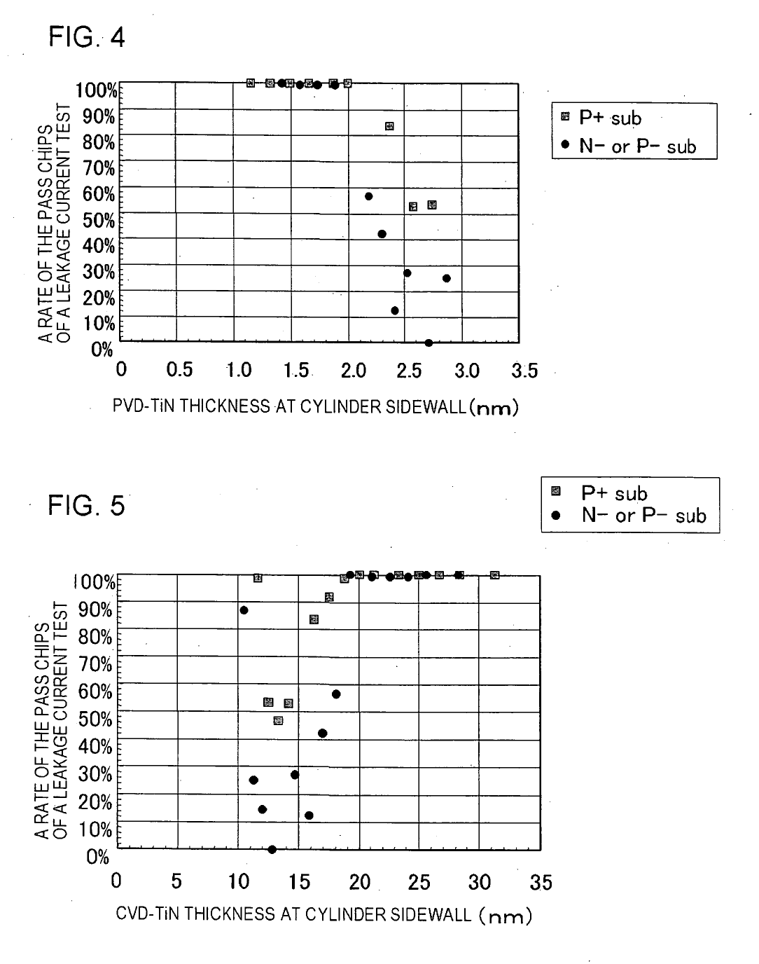

FIG. 4 shows a relation between a thickness of the cylinder sidewall of the PVD layer 116 and a rate of the pass chips of a leakage current test. 159 pieces of chips have been evaluated.

As shown in FIG. 4, when the cylinder sidewall of the PVD layer 116 has a thickness of 2 nm or less, the rate of the pass chips of the leakage current test was substantially 100%. By contrast, as the cylinder sidewall of the PVD layer 116 becomes thicker, the rate of the pass chips was lowered. Assumingly this is because the Ta₂O₅ film has been damaged when depositing the PVD layer 116, and thereby the initial leakage current has been lowered.

### SECOND EXAMPLE

Similar steps to those described referring to FIGS. 2A through 3H have been taken so as to form the capacitor 124. In this example, different conditions have been applied to the deposition of the CVD layer 118 (TiN), such that the thickness of the cylinder sidewall of the CVD layer 118 becomes 10 to 33 nm. In this example, the capacitance layer 114 was constituted of a Ta₂O₅ film; the PVD layer 116 was constituted of TiN; and the buried metal layer 122 was constituted of W. The cylinder sidewall of the PVD layer 116 has been formed in a thickness of 2 nm or less, and the CVD layer 118 has been deposited under a temperature of 435 degree centigrade.

FIG. 5 shows a relation between a thickness of the cylinder sidewall of the CVD layer 118 and a rate of the pass chips of a leakage current test. 159 pieces of chips have been evaluated.

As shown in FIG. 5, when the cylinder sidewall of the CVD layer 118 has a thickness of 20 nm or more, the rate of the pass chips of a leakage current test was substantially 100%. By contrast, as the cylinder sidewall of the CVD layer 118 becomes thinner, the rate of the pass chips was lowered. Assumingly, this is because the overall thickness of the upper electrode 120 has resulted insufficient owing to the lack of thickness of the CVD layer 118, and the capacitance layer 114 has been thereby damaged when depositing the buried metal layer 122 and in the subsequent process.

### THIRD EXAMPLE

Similar steps to those described referring to FIGS. 2A through 3H have been taken so as to form the capacitor 124. In this example, different temperatures, specifically in a range of 350 to 470 degree centigrade, have been applied to the deposition of the CVD layer 118 (TiN). In this example, the capacitance layer 114 was constituted of a Ta₂O₅ film; the PVD layer 116 was constituted of TiN; and the buried metal layer 122 was constituted of W. The cylinder sidewall of the PVD layer 116 has been formed in a thickness of 2 nm or less, and the cylinder sidewall of the CVD layer 118 has been formed a thickness of 30 nm.

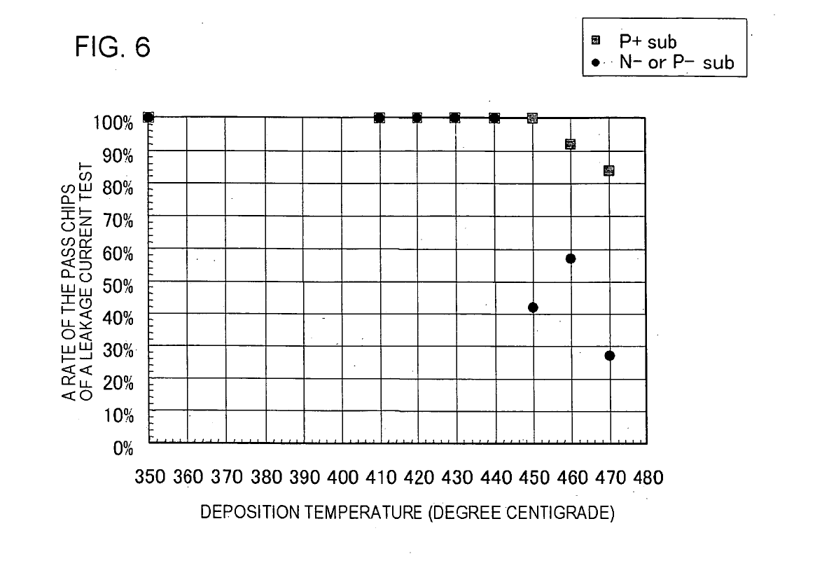

FIG. 6 shows a relation between a temperature under which the CVD layer 118 has been deposited and a rate of the pass chips of a leakage current test. 159 pieces of chips have been evaluated.

As shown in FIG. 6, when the CVD layer 118 was deposited under a temperature of 440 degree centigrade or lower, the rate of the pass chips of a leakage current test was substantially 100% irrespective of the concentration of the impurities in the silicon substrate. By contrast, as the deposition temperature of the CVD layer 118 was increased, the rate of the pass chips was lowered. Assumingly this is because a temperature not exceeding 440 degree centigrade allows preventing the capacitance layer 114 from being damaged by a chemical gas such as hydrogen during the deposition of the CVD layer 118, and improving the coverage performance thereof.

As is apparent in view of the foregoing examples, forming the PVD layer 116 such that the cylinder sidewall has a thickness of 2 nm or less effectively contributed in increasing the rate of the pass chips. Also, forming the CVD layer 118 such that the sidewall has a thickness of 20 nm or more was effective in increasing the rate of the pass chips. Further, depositing the CVD layer 118 under a temperature not exceeding 440 degree centigrade has also proved to be effective in increasing the rate of the pass chips. Applying these conditions in combination to the formation of a capacitor allows reducing a leakage current in a semiconductor device including a MIM capacitor, and assuring further the advantage of suppressing degradation in capacitance characteristics and in initial leakage current of the capacitor.

Although the present invention has been described in details based on the embodiment and examples, it is to be understood that they are only exemplary and that various other structures and arrangements may be adopted.

It is apparent that the present invention is not limited to the above embodiment, that may be modified and changed without departing from the scope and spirit of the invention.

What is claimed is:

1. A semiconductor device including a cylinder-shaped capacitor, comprising:
a semiconductor substrate;
an insulating layer which is formed on said semiconductor substrate and formed with a recessed portion;
a cylinder-shaped lower electrode constituted of a metal material formed in said recessed portion of said insulating layer;
a capacitance layer formed on said lower electrode; and
an upper electrode formed on said capacitance layer;
wherein said upper electrode includes a first metal layer formed by a PVD process and a second metal layer formed on said first metal layer by a CVD process; and wherein a cylinder sidewall of said first metal layer has a thickness of 2 nm or less.

2. The semiconductor device according to claim 1, wherein said capacitance layer is constituted of a high dielectric constant film.

3. The semiconductor device according to claim 1, wherein said capacitance layer is constituted of a Ta₂O₅ film.

4. The semiconductor device according to claim 1, wherein said first metal layer and said second metal layer of said upper electrode are constituted of a titanium nitride.

5. The semiconductor device according to claim 1, wherein said lower electrode is constituted of a titanium nitride.

6. The semiconductor device according to claim 1, wherein a sidewall of said second metal layer has a thickness of 20 nm or more.

7. The semiconductor device according to claim 1, wherein said upper electrode includes a buried metal layer that fills said recessed portion and formed on said second metal layer.

8. The semiconductor device according to claim 3, wherein said first metal layer and said second metal layer of said upper electrode are constituted of a titanium nitride.

9. The semiconductor device according to claim 8, wherein said lower electrode is constituted of a titanium nitride.

10. The semiconductor device according to claim 4, wherein said lower electrode is constituted of a titanium nitride.

11. The semiconductor device according to claim 3, wherein a sidewall of said second metal layer has a thickness of 20 nm or more.

12. The semiconductor device according to claim 4, wherein a sidewall of said second metal layer has a thickness of 20 nm or more.

13. A method of manufacturing a semiconductor device, comprising:
forming an insulating layer on a semiconductor substrate;
forming a recessed portion in said insulating layer; and
forming in said recessed portion a cylinder-shaped capacitor, including a lower electrode constituted of a metal material, a capacitance layer formed on said lower electrode and an upper electrode formed on said capacitance layer;
wherein said forming said capacitor includes forming said upper electrode by forming a first metal layer by a PVD process such that its thickness at a sidewall of said cylinder becomes 2 nm or less, and forming a second metal layer on said first metal layer by a CVD process.

14. The method according to claim 13, wherein said forming said first metal layer includes performing a long-throw sputtering process, with a spacing of 150 mm or more between a target and said substrate.

15. The method according to claim 13, wherein said forming said second metal layer is performed under a temperature not exceeding 440 degree centigrade.

16. The method according to claim 14, wherein said forming said second metal layer is performed under a temperature not exceeding 440 degree centigrade.
